(19) United States
(12) Patent Application Publication
(10) Pub. No.: US 2026/0198187 A1
(43) Pub. Date: Jul. 9, 2026

(54) DISPLAY PANEL, MANUFACTURING METHOD THEREFOR, AND DISPLAY DEVICE

(71) Applicants: Beijing BOE Technology Development Co., Ltd., Beijing (CN); BOE Technology Group Co., Ltd., Beijing (CN)

(72) Inventors: Yue ZHANG, Beijing (CN); Juanjuan YOU, Beijing (CN); Shuilang DONG, Beijing (CN); Dandan ZHOU, Beijing (CN); Bin BU, Beijing (CN); Yongqi SHEN, Beijing (CN); Wei QUAN, Beijing (CN)

(21) Appl. No.: 18/863,806

(22) PCT Filed: Aug. 16, 2024
(86) PCT No.: PCT/CN2024/112720

§ 371 Date: Nov. 7, 2024

(30) Foreign Application Priority Data
Sep. 26, 2023 (CN) 202311251525.8

(51) Int. Cl. H10K 59/124; H10K 59/12; H10K 59/35; H10K 59/80

(52) U.S. Cl. CPC H10K 59/124; H10K 59/1201; H10K 59/352; H10K 59/879

(57) ABSTRACT

A display panel is provided. The display panel includes a substrate, and a plurality of pixel units and an organic insulating layer disposed on the substrate. The organic insulating layer is disposed between a driver circuit and a light-emitting unit of the pixel unit. A lens assembly is arranged on a surface, away from the substrate, of a portion of the organic insulating layer within a light-emitting region of any of the plurality of pixel units. The lens assembly comprises a plurality of lenses with adjacent lenses forming taper structures. A first surface and a second surface, away from the substrate, of the taper structure are configured to reflect light, that is confined to the interior of the display panel, to a light-emitting side.

### CROSS-REFERENCE TO RELATED APPLICATIONS

This application is a U.S. national stage of international application No. PCT/CN2024/112720, filed on Aug. 16, 2024, which claims priority to Chinese Patent Application No. 202311251525.8, filed on Sep. 26, 2023, and entitled “DISPLAY PANEL, PREPARATION METHOD THEREOF AND DISPLAY DEVICE,” the disclosures of which are herein incorporated by reference in their entireties.

### TECHNICAL FIELD

The present disclosure relates to the field of display technologies, and in particular, to a display panel, a manufacturing method therefor, and a display device.

### BACKGROUND

Organic light-emitting diode (OLED) display panels are widely applied due to their advantages of self-luminescence, fast response, wide viewing angle, high brightness, bright colors, small weight, and small thickness.

### SUMMARY

The present disclosure provides a display panel, a manufacturing method therefor, and a display device. The technical solutions are as follows.

According to some aspects, a display panel is provided. The display panel includes:
a substrate, wherein the substrate includes a display region and a peripheral region surrounding the display region;
a plurality of pixel units, wherein the plurality of pixel units are disposed on a side of the substrate and within the display region, and each of the plurality of pixel units includes a driver circuit and a light-emitting unit, the light-emitting unit being connected to the driver circuit to receive a drive signal from the driver circuit; and
an organic insulating layer, wherein the organic insulating layer is disposed between the driver circuit and the light-emitting unit;
wherein a lens assembly is arranged on a surface, away from the substrate, of a portion of the organic insulating layer within a light-emitting region of the pixel unit, the lens assembly including a plurality of lenses with adjacent lenses forming taper structures, and at least one of the taper structures including a first surface and a second surface on a side, away from the substrate, of the at least one of taper structures.

In some embodiments, each of the taper structures includes a first end, a second end, and a middle portion between the first end and the second end, at least one of the first end or the second end of each of the taper structures being connected to a first end or a second end of another taper structure;
wherein a width of an orthographic projection of each of the first end and the second end of the taper structure on the substrate is greater than a width of an orthographic projection of the middle portion of the taper structure on the substrate, a direction of the width being perpendicular to a direction of a line connecting the first end and the second end.

In some embodiments, each of the taper structures includes a first end, a second end, and a middle portion between the first end and the second end, at least one of the first end or the second end of each of the taper structures being connected to a first end or a second end of another taper structure;
wherein a height of each of the first end and the second end of the taper structure is greater than a height of the middle portion of the taper structure, a direction of the height being perpendicular to a bearing surface of the substrate.

In some embodiments, a mesh structure is formed on a side, away from the substrate, of the taper structure, the mesh structure including a plurality of grids arranged in an array, wherein the plurality of grids have the same shape.

In some embodiments, at least one of the grids in the mesh structure is shaped as a quadrilateral or a hexagon.

In some embodiments, an orthographic projection of a region enclosed by at least one of the grids on the substrate is shaped as a circle.

In some embodiments, an area of a surface, away from the substrate, of the taper structure within a light-emitting region of each of the plurality of pixel units is smaller than an area of the light-emitting region of the pixel unit.

In some embodiments, the light-emitting unit includes an anode layer, a light-emitting layer, and a cathode layer that are sequentially stacked in a direction away from the substrate, and the display panel further includes a pixel defining layer; wherein
the anode layer includes a plurality of anode patterns; the pixel defining layer includes a plurality of hollow regions, each of the hollow regions exposing one of the anode patterns; the light-emitting layer includes a plurality of light-emitting patterns, each of the light-emitting patterns being in contact with one of the anode patterns through one of the hollow regions; and the cathode layer is in contact with the light-emitting pattern; wherein the hollow region is the light-emitting region; and
a total thickness of the anode pattern, the light-emitting pattern, and a portion of the cathode layer on the first surface and the second surface is less than a total thickness of the anode pattern, the light-emitting pattern, and other portion of the cathode layer.

In some embodiments, the plurality of pixel units include a first pixel unit, a second pixel unit, and a third pixel unit;
the lens assembly includes a first-type lens assembly, a second-type lens assembly, and a third-type lens assembly, an orthographic projection of the first-type lens assembly on the substrate being within a light-emitting region of the first pixel unit, an orthographic projection of the second-type lens assembly on the substrate being within a light-emitting region of the second pixel unit, an orthographic projection of the third-type lens assembly on the substrate being within a light-emitting region of the third pixel unit;
wherein a first angle defined between a first surface or a second surface of a taper structure formed by a lens of the first-type lens assembly and a bearing surface of the substrate, a second angle defined between a first surface or a second surface of a taper structure formed by a lens of the second-type lens assembly and the bearing surface of the substrate, and a third angle defined between a first surface or a second surface of a taper structure formed by a lens of the third-type lens assembly and the bearing surface of the substrate are different from each other.

In some embodiments, the first pixel unit is a blue pixel unit, the second pixel unit is a green pixel unit, and the third pixel unit is a red pixel unit; and
the first angle is greater than the second angle, and the second angle is greater than the third angle.

In some embodiments, the first angle ranges from 56 degrees to 60 degrees, the second angle ranges from 40 degrees to 44 degrees, and the third angle ranges from 29 degrees to 33 degrees.

In some embodiments, any of the taper structures includes: a first intersection line of the first surface and a second intersection line of the second surface; wherein
both the first intersection line and the second intersection line are straight lines; or, both the first intersection line and the second intersection line are curves; wherein
both the first intersection line and the second intersection line are intersection lines of a middle portion of the taper structure with a reference plane, the reference plane being perpendicular to a length direction of the taper structure and perpendicular to a bearing surface of the substrate; and the first intersection line and the second intersection line are symmetrical relative to a central axis of the taper structure along the length direction.

In some embodiments, the display panel further includes: a color filter layer disposed between the organic insulating layer and the driver circuit, the color filter layer including a plurality of color filter blocks of different colors; wherein
an orthographic projection of each of the color filter blocks on the substrate covers a light-emitting region of one of the plurality of pixel units.

In some embodiments, a light-emitting side of the display panel is a side, away from the plurality of pixel units, of the substrate; and
the first surface and the second surface are configured to reflect light from a side of the substrate, and the reflected light by the first surface and the second surface passes through any of the plurality of color filter blocks and exits from the side, away from the plurality of pixel units, of the substrate.

According to some aspects, a method for manufacturing a display panel is provided. The method includes:
acquiring a substrate, wherein the substrate includes a display region and a peripheral region surrounding the display region;
forming driver circuits of a plurality of pixel units;
forming an organic insulating film on a side, away from the substrate, of the driver circuits;
forming a metal mask on a side, away from the substrate, of the organic insulating film;
acquiring an organic insulating layer by etching the organic insulating film using the metal mask;
removing the metal mask; and
forming light-emitting units of the plurality of pixel units on a side, away from the substrate, of the organic insulating layer, the light-emitting units being connected to the driver circuits to receive drive signals from the driver circuits;
wherein a lens assembly is arranged on a surface, away from the substrate, of a portion of the organic insulating layer within a light-emitting region of any of the plurality of pixel units, the lens assembly including a plurality of lenses with adjacent lenses forming taper structures, and at least one of the taper structures including a first surface and a second surface on a side, away from the substrate, of the at least one of taper structures, the first surface and the second surface being configured to reflect light.

According to some aspects, a display device is provided. The display device includes: a power supply assembly and a display panel as described in the above aspects;
wherein the power supply assembly is configured to supply power to the display panel.

### BRIEF DESCRIPTION OF DRAWINGS

In order to describe the technical solutions in the embodiments of the present disclosure more clearly, the following briefly introduces the accompanying drawings required for describing the embodiments. Apparently, the accompanying drawings in the following description show merely some embodiments of the present disclosure, and a person skilled in the art can still derive other drawings from these accompanying drawings without creative efforts.

FIG. 1 is a schematic structural diagram of a display panel according to some embodiments of the present disclosure;

FIG. 2 is a top view of a substrate and a pixel unit according to some embodiments of the present disclosure;

FIG. 3 is a partial top view of hexagonal grids according to some embodiments of the present disclosure;

FIG. 4 is a partial schematic diagram of an organic insulating layer according to some embodiments of the present disclosure;

FIG. 5 is a partial top view of quadrilateral grids according to some embodiments of the present disclosure;

FIG. 6 is a schematic diagram of a taper structure according to some embodiments of the present disclosure;

FIG. 7 is a schematic diagram of another taper structure according to some embodiments of the present disclosure;

FIG. 8 is a schematic diagram of yet another taper structure according to some embodiments of the present disclosure;

FIG. 9 is a schematic diagram of a light path according to some embodiments of the present disclosure;

FIG. 10 is a flowchart of a method for manufacturing a display panel according to some embodiments of the present disclosure;

FIG. 11 is a schematic diagram of forming an organic insulating film according to some embodiments of the present disclosure;

FIG. 12 is a schematic diagram of forming a metal mask according to some embodiments of the present disclosure;

FIG. 13 is a partial top view of a metal mask according to some embodiments of the present disclosure;

FIG. 14 is a schematic diagram of forming an organic insulating layer according to some embodiments of the present disclosure;

FIG. 15 is a partial schematic diagram of another organic insulating layer according to some embodiments of the present disclosure; and

FIG. 16 is a schematic structural diagram of a display device according to some embodiments of the present disclosure.

### DETAILED DESCRIPTION

To make the objectives, technical solutions, and advantages of the present disclosure clearer, the embodiments of the present disclosure are further described hereinafter with reference to the accompanying drawings.

In the related art, OLED display panels may be display panels in which red, green, and blue (RGB, which are the three primary colors) OLED devices emit light separately. Such display panels can be manufactured through a simple and mature method that is easy to operate. However, due to the need for high-precision masks and precise alignment when manufacturing high-resolution display panels, the capacity of the high-resolution display panels is low and the cost is high. Moreover, due to the large differences in the service life, excitation rate, and degree of decay of RGB (the three primary colors) OLED devices, a color deviation of the OLED display panels easily occurs.

Therefore, a new OLED display panel is provided, which employs the technology of combining a white OLED device with a color filter, and thus avoids the mask alignment. This kind of OLED display panel usually adopts a light-emitting manner of bottom-emitting, which greatly simplifies the vapor deposition process, and thus the technology can be used to manufacture large-size and high-resolution OLED panels.

However, for OLED display panels combining a white OLED device and a color filter, light emitted by the OLED device with a large exit angle is reflected into the OLED device, resulting in a reduction in the light-emitting amount of the OLED display panel and a poorer display effect.

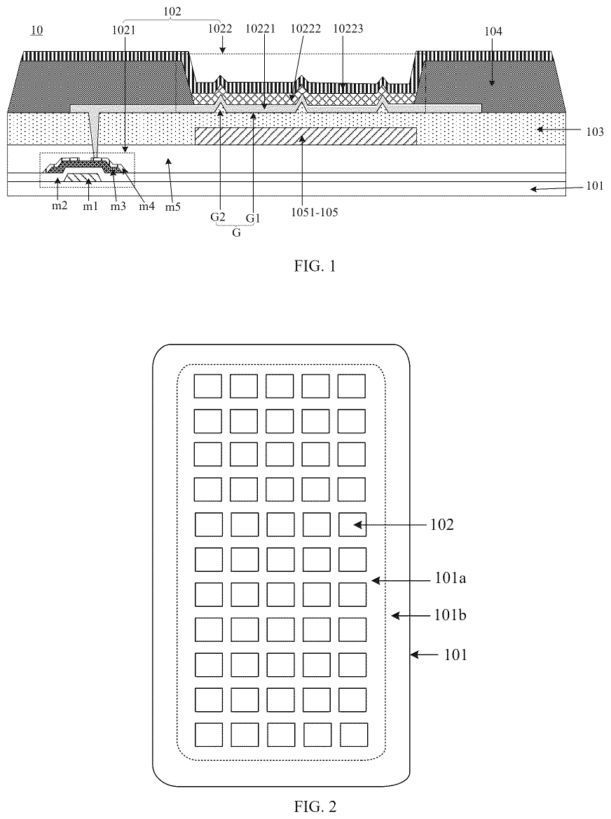

FIG. 1 is a schematic structural diagram of a display panel according to some embodiments of the present disclosure. Referring to FIG. 1, the display panel includes: a substrate 101, a plurality of pixel units 102, and an organic insulating layer 103.

FIG. 2 is a top view of a substrate and a pixel unit according to some embodiments of the present disclosure. Referring to FIG. 2, the substrate 101 includes a display region 101a and a peripheral region 101b surrounding the display region 101a.

Combining FIGS. 1 and 2, the plurality of pixel units 102 are disposed within the display region 101a. Each of the plurality of pixel units 102 includes a driver circuit 1021 and a light-emitting unit 1022, wherein the light-emitting unit 1022 is connected to the driver circuit 1021 to receive a drive signal from the driver circuit 1021.

Further, the organic insulating layer 103 in the display panel 10 is disposed between the driver circuit 1021 and the light-emitting unit 1022. In some embodiments, the organic insulating layer 103 is provided with a via hole configured for connection of the light-emitting unit 1022 and the driver circuit 1021. In some embodiments, the organic insulating layer 103 is a planarization layer (PLN).

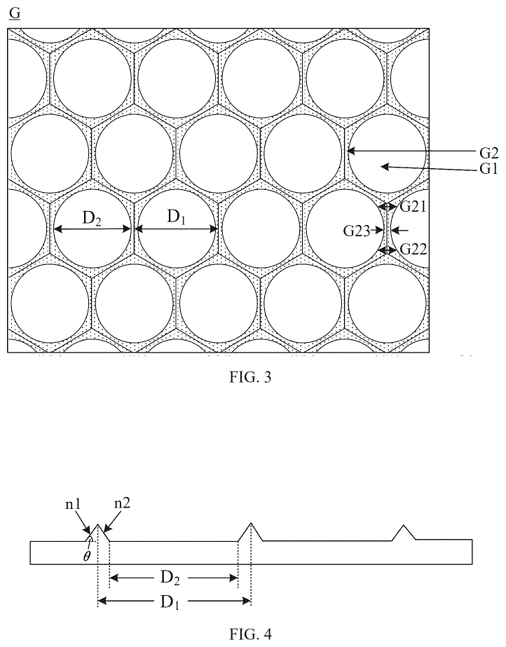

In some embodiments of the present disclosure, each pixel unit 102 has a light-emitting region, wherein the light-emitting region of the pixel unit 102 is configured to emit light. A lens assembly G is arranged on a surface, away from the substrate 101, of a portion of the organic insulating layer 103 within the light-emitting region of the pixel unit 102. Referring to FIGS. 3 and 4, the lens assembly G includes a plurality of lenses G1 with any two adjacent lenses forming a taper structure G2, wherein each taper structure G2 includes a first surface n1 and a second surface n2 on a side, away from the substrate 101, of the taper structure G2.

A portion of the light emitted from the light-emitting region of the pixel unit 102 is possible with a large angle, and thus this portion of the light is confined to the interior of the display panel 10 and can not exit. Providing the lens assembly G on the side, away from the substrate 101, of the organic insulating layer 103 causes at least a portion of the light rays confined to the interior of the display panel 10 to irradiate to the first surface n1 and the second surface n2 of the taper structure G2. Further, the light rays irradiating to the first surface n1 and the second surface n2 are reflected by the first surface n1 and the second surface n2 to a light-emitting side, which increases the light-emitting amount and improves the light extraction effect, and ensures the light-emitting effect of the display panel 10.

In summary, the embodiments of the present disclosure provide a display panel. The display panel includes a substrate, and a plurality of pixel units and an organic insulating layer disposed on the substrate. The organic insulating layer is disposed between a driver circuit and a light-emitting unit of the pixel unit, and a lens assembly is arranged on a surface, away from the substrate, of a portion of the organic insulating layer within a light-emitting region of the pixel unit. The lens assembly includes a plurality of lenses with any two adjacent lenses forming a taper structure. A first surface and a second surface, away from the substrate, of the taper structure are configured to reflect the light confined to the interior of the display panel to the light-emitting side, which improves the light-emitting amount and the light extraction effect and ensures the light-emitting effect of the display panel.

In conjunction with FIG. 3, each taper structure G2 includes a first end G21, a second end G22, and a middle portion G23 between the first end G21 and the second end G22. At least one of the first end G21 or the second end G22 of each taper structure G2 is connected to a first end G21 or a second end G22 of another taper structure G2. In some embodiments, the lens assembly G corresponding to the light-emitting region of each pixel unit 102 is an integrative structure.

In some embodiments, a width of an orthographic projection of each of the first end G21 and the second end G22 of the taper structure G2 on the substrate 101 is greater than a width of an orthographic projection of the middle portion G23 of the taper structure G2 on the substrate 101. A direction of the width is perpendicular to a direction of a line connecting the first end G21 and the second end G22.

In some embodiments, a height of each of the first end G21 and the second end G22 of the taper structure G2 is greater than a height of the middle portion G23 of the taper structure G2. A direction of the height is perpendicular to a bearing surface of the substrate 101.

In some embodiments of the present disclosure, the taper structure G2 is formed by etching using a metal hard mask formed on an organic insulating film. Under the influence of the etching process, the width as well as the height of the middle portion G23 of the taper structure G2 are usually smaller than the widths as well as the heights of the two ends. In some other embodiments, the width and height of the middle portion G23 of the taper structure G2 are not smaller than the widths and the heights of the two ends.

Referring to FIG. 3, a mesh structure is formed on a side, away from the substrate, of the taper structure G2. The mesh structure includes a plurality of grids arranged in an array, wherein the plurality of grids have the same shape. In this way, the light emitted from the light-emitting region is made more uniform to ensure the light-emitting uniformity of the light-emitting region.

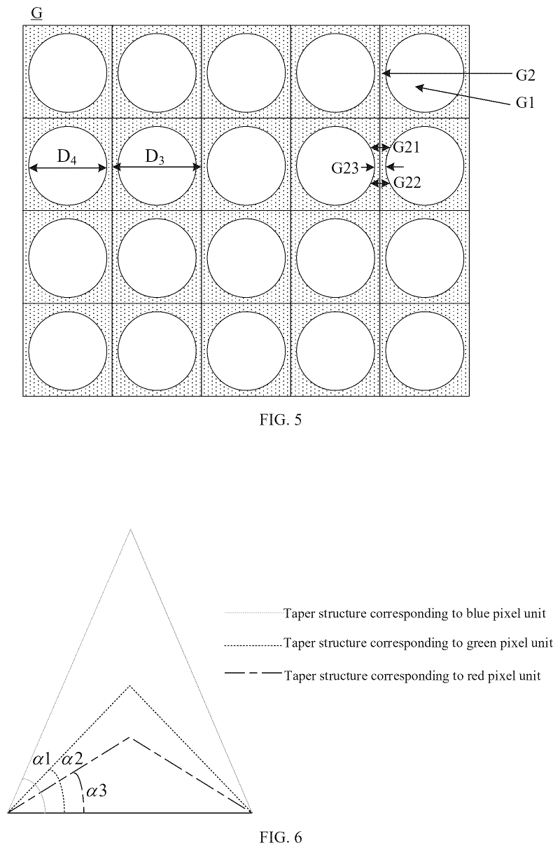

In some embodiments, referring to FIG. 3, the grid is shaped as a hexagon. Alternatively, referring to FIG. 5, the grid is shaped as a quadrilateral. The shape of the grid is not limited in the embodiments of the present disclosure.

Further, referring to FIGS. 3 and 5, an orthographic projection of a region enclosed by each grid (the region enclosed by the grid being the lens G1) on the substrate 101 is shaped as a circle. Because each point on the circle is at an equal distance from the center of the circle, making the shape of the region enclosed by each grid a circle ensures that the distance between any position of each taper structure G2 and the center of the circle is equal. In this way, the uniformity of the light extraction effect of any position of the first surface n1 or the second surface n2 of the taper structure G2 is ensured, and thus the display effect is ensured.

In some embodiments of the present disclosure, the presence of the taper structure G2 results in that the various film layers of the light-emitting unit 1022 subsequently formed on the side, away from the substrate 101, of the organic insulating layer 103 are formed not only on the first surface n1 and the second surface n2 of the taper structure G2, but also within the regions enclosed by the grids formed by the plurality of taper structures G2 (i.e., the regions where the lenses are located.)

In some embodiments, both the first surface n1 and the second surface n2 are bevel surfaces, and the surface of the region in which the lens is located is a flat surface or an arc surface.

In the case that the surface of the region in which the lens G1 is located is an arc surface, the first surface n1, the second surface n2, and the lens G1 of the taper structure G2 are arc surfaces that continuously extend. At any position of the arc surface, the film thicknesses of various film layers of the light-emitting unit 1022 do not differ significantly.

In the case that the surface of the region in which the lens is located is a flat surface as shown in FIG. 1, because the first surface n1 and the second surface n2 of the taper structure G2 are bevel surfaces, the film layer thicknesses of the various film layers of the light-emitting unit 1022 disposed on the bevel first surface n1 and the bevel second surface n2 are smaller than the film layer thicknesses of the various film layers of the light-emitting unit 1022 disposed on the flat surface.

That is, the light-emitting unit 1022 includes: an anode layer 10221, a light-emitting layer 10222, and a cathode layer 10223 that are sequentially stacked in a direction away from the substrate 101. Further, the display panel 101 includes a pixel defining layer 104. The anode layer 10221 includes a plurality of anode patterns, and the pixel defining layer 104 includes a plurality of hollow regions, each of the hollow regions exposing one of the plurality of anode patterns. The light-emitting layer 10222 includes a plurality of light-emitting patterns, each light-emitting pattern being in contact with one anode pattern through one of the hollow regions. The cathode layer 10223 is in contact with the light-emitting pattern. In some embodiments, the hollow region is the light-emitting region of the pixel unit 102.

A total thickness of the anode pattern, the light-emitting pattern, and a portion of the cathode layer 10223 on the first surface n1 and the second surface n2 is less than a total thickness of the anode pattern, the light-emitting pattern, and the other portion of the cathode layer 10223.

Because light is more easily emitted at locations where the thickness of the film layer of the light-emitting unit 1022 is smaller and less easily emitted at locations where the thickness of the film layer is larger, the actual light-emitting region of the light-emitting region of the pixel unit 102 is the region where the first surfaces n1 and the second surfaces n2 of the plurality of taper structures G2 are located. That is, the actual light-emitting area of the light-emitting region of the pixel unit 102 is the area of the plurality of taper structures G2.

In some embodiments of the present disclosure, to increase the light-emitting efficiency in the case of providing the same current to the pixel unit 102, the actual light-emitting area of the light-emitting region of the pixel unit 102 needs to be reduced to increase the current density.

That is, the condition to be satisfied in the embodiments of the present disclosure is that, an area of a surface, away from the substrate 101, of the taper structure G2 within the light-emitting region of the pixel unit 102 (i.e., the actual light-emitting area), is smaller than the area of the light-emitting region of the pixel unit 102.

Assuming that the shape of the grid included in the mesh structure is hexagonal, the condition to be satisfied is:

$${S}_{taper} < {S}_{hexagon} \qquad Formula ( 1 )$$

wherein S_{hexagon} represents the area of a hexagonal grid and S_{hexagon} satisfies:

$${S}_{hexagon} = \frac{\sqrt{3}}{2} {D}_{1}^{2} \qquad Formula ( 2 )$$

Sₜₐₚₑᵣ represents the area of a taper structure G2 within a hexagonal grid and Sₜₐₚₑᵣ satisfies:

$${S}_{taper} = \frac{\frac{\sqrt{3}}{2} {D}_{1}^{2} - {π ( \frac{{D}_{2}}{2} )}^{2}}{cos θ} \qquad Formula ( 3 )$$

The following equation is acquired by substituting Formula (2) and Formula (3) into Formula (1):

$$\frac{\frac{\sqrt{3}}{2} {D}_{1}^{2} - {π ( \frac{{D}_{2}}{2} )}^{2}}{cos θ} < \frac{\sqrt{3}}{2} {D}_{1}^{2} \qquad Formula ( 4 )$$

In the above Formula (2) to Formula (4), D₁ represents a distance between the centre lines of two taper structures G2 that are parallel to each other in the hexagonal grid, D₂ represents a diameter of a circle of the region (lens G1) enclosed by the hexagonal grid formed by the plurality of taper structures G2, and θ represents the angle between the first surface n1 or the second surface n2 of the taper structure G2 and a bearing surface of the substrate 101.

Among the light emitted from the light-emitting side of the display panel, the light with a larger exit angle is reflected into the display panel 10 and can not exit. To make the taper structure G2 achieve a light extraction effect, the emitted light needs to be reflected multiple times within the taper structure G2, such that the light is able to propagate at an angle smaller than the critical angle of total reflection, and thus the light confined in the display panel is extracted.

For the hexagonal grid scenario, it is derived from optical simulations that the angle θ ranges from 20 degrees to 45 degrees, and the D₁ ranges from 3 μm (micrometers) to 8 μm. In the embodiments of the present disclosure, by selecting a suitable angle θ as well as a suitable D₁, the range of D₂ is calculated according to the above Formula (4).

Assuming that the shape of the grid included in the mesh structure is quadrilateral, the condition to be satisfied is:

$${S}_{taper} < {S}_{quadrilateral} \qquad Formula ( 5 )$$

wherein S_{quadrilateral} represents the area of a quadrilateral grid and S_{quadrilateral} satisfies:

$${S}_{quadrilateral} = {D}_{3}^{2} \qquad Formula ( 6 )$$

Sₜₐₚₑᵣ represents the area of a taper structure G2 within the range of a quadrilateral grid and Sₜₐₚₑᵣ satisfies:

$${S}_{taper} = \frac{{D}_{3}^{2} - {π ( \frac{{D}_{4}}{2} )}^{2}}{cos θ} \qquad Formula ( 7 )$$

The following Formula is acquired by substituting Formula (6) and Formula (7) into Formula (5):

$$\frac{{D}_{3}^{2} - {π ( \frac{{D}_{4}}{2} )}^{2}}{cos θ} < {D}_{3}^{2} \qquad Formula ( 8 )$$

In the above Formula (5) to Formula (8), D₃ represents a distance between centre lines of two taper structures G2 that are parallel to each other in the quadrilateral grid, and D₄ represents a diameter of a circle of a region (lens G1) enclosed by a quadrilateral grid formed by a plurality of taper structures G2, and θ represents the angle between the first surface n1 or the second surface n2 of the taper structure G2 and the bearing surface of the substrate 101.

For the quadrilateral grid scenario, it is derived from optical simulation that the angle θ o ranges from 20 degrees to 45 degrees, and D₃ ranges from 3 μm to 8 μm. In the embodiments of the present disclosure, by selecting a suitable angle θ as well as a suitable D₃, the range of D₄ is calculated according to the above Formula (4).

In some embodiments, because the actual light-emitting area of the light-emitting region of the pixel unit 102 is small, the current density is increased to increase the brightness of the pixel unit 102. Combined with the light extraction effect of the taper structure G2, the overall brightness of the display panel 10 is higher and the display effect is better.

In some embodiments of the present disclosure, the plurality of pixel units 102 includes: a first pixel unit, a second pixel unit, and a third pixel unit. The first pixel unit, the second pixel unit, and the third pixel unit emit light of different colors.

The lens assembly G includes a first-type lens assembly, a second-type lens assembly, and a third-type lens assembly. An orthographic projection of the first-type lens assembly on the substrate 101 is within the light-emitting region of the first pixel unit. An orthographic projection of the second-type lens assembly on the substrate 101 is within the light-emitting region of the second pixel unit. An orthographic projection of the third-type lens assembly on the substrate 101 is within the light-emitting region of the third pixel unit.

A first angle defined between a first surface n1 or a second surface n2 of a taper structure G2 formed by the lens G1 of the first-type lens assembly and the bearing surface of the substrate 101, a second angle defined between a first surface n1 or a second surface n2 of a taper structure G2 formed by the lens G1 of the second-type lens assembly and the bearing surface of the substrate 101, and a third angle defined between a first surface n1 or a second surface n2 of a taper structure G2 formed by the lens G1 of the third-type lens assembly and the bearing surface of the substrate 101 are different from each other.

Because the colors of the first pixel unit, the second pixel unit, and the third pixel unit are different from each other, and the properties of the pixel units 102 of different colors are different, the service lives of the first pixel unit, the second pixel unit, and the third pixel unit are different from each other, which in turn leads to a poorer display effect of the display panel upon a period of use.

Typically, the larger the actual light-emitting area of the light-emitting region of the pixel unit 102 is, the lower the current density is, and the longer the service life is. To balance the service lives of the pixel units 102 of different colors, the actual light-emitting area of the light-emitting region of the pixel unit 102 with a shorter service life is made larger than the actual light-emitting area of the light-emitting region of the pixel unit 102 with a longer service life.

Further, the actual light-emitting area of the light-emitting region of the pixel unit 102 in the embodiments of the present disclosure is the sum of the areas of the first surface n1 and the second surface n2 of the taper structure G2. To adjust the sum of the areas of the first surface n1 and the second surface n2 of the taper structure G2, the angle between the first surface n1 as well as the second surface n2 of the taper structure G2 and the bearing surface of the substrate 101 is adjusted in the case that the width of the taper structure G2 is constant.

Referring to FIG. 6, the larger the angle between the first surface n1 as well as the second surface n2 of the taper structure G2 and the bearing surface of the substrate 101, the larger the sum of the areas of the first surface n1 and the second surface n2 of the taper structure G2, and the larger the actual light-emitting area of the light-emitting region of the pixel unit 102. The smaller the angle between the first surface n1 as well as the second surface n2 of the taper structure G2 and the bearing surface of the substrate 101, the smaller the sum of the areas of the first surface n1 and the second surface n2 of the taper structure G2, the smaller the actual light-emitting area of the light-emitting region of the pixel unit 102.

In some embodiments of the present disclosure, by making the angles, between the first surface n1 as well as the second surface n2 of the taper structure G2 formed by the lens included in the lens assembly G and the bearing surface of the substrate 101, corresponding to the pixel units 102 of different colors different, the angle relationship is adjusted based on the service life relationship of the pixel units 102, thereby balancing the service lives of the pixel units 102 of different colors.

In some embodiments, the first pixel unit is a blue pixel unit, the second pixel unit is a green pixel unit, and the third pixel unit is a red pixel unit. Typically, the ratio of the service lives of the blue pixel unit, the green pixel unit, and the red pixel unit is 1:1.7:2. That is, the blue pixel unit has the shortest service life, the red pixel unit has the longest service life, and the green pixel unit has a service life longer than the service life of the blue pixel unit and shorter than the service life of the red pixel unit.

To balance the service lives of the pixel units 102, it is necessary to make the actual light-emitting area of the light-emitting region of the blue pixel unit larger than the actual light-emitting area of the light-emitting region of the green pixel unit, and the actual light-emitting area of the light-emitting region of the green pixel unit larger than the actual light-emitting area of the light-emitting region of the red pixel unit. As a result, it is necessary to make the first angle α1 greater than the second angle α2, and the second angle α2 greater than the third angle α3. FIG. 6 illustrates an angle relationship of the taper structures formed by the lenses corresponding to the pixel units of different colors and is not intended to indicate a positional relationship of the taper structures corresponding to the pixel units of different colors.

In some embodiments, the first angle ranges from 56 degrees to 60 degrees, the second angle ranges from 40 degrees to 44 degrees, and the third angle ranges from 29 degrees to 33 degrees. In some embodiments, the first angle is 58 degrees, the second angle is 42 degrees, and the third angle is 31 degrees.

In the embodiments of the present disclosure, the actual light-emitting area of the light-emitting region of the pixel unit 102 is adjusted by adjusting the angles between the first surface n1 as well as the second surface n2 of the taper structure G2 and the bearing surface of the substrate 101, which in turn adjusts the current density of the pixel unit 102 and then adjusts the service life of the pixel unit 102. In some embodiments, assuming that the ratio of the current densities of two pixel units 102 is 1:2, the ratio of the service lives of the two pixel units 102 is 21.5.1.

In some embodiments, the plurality of pixel units 102 further include a fourth pixel unit. In the case that the fourth pixel unit is a white pixel unit, the light-emitting region of the fourth pixel unit is provided with a lens assembly G or without a lens assembly G, which is not limited in the embodiments of the present disclosure.

In some embodiments of the present disclosure, the taper structure G2 includes: a first intersection line of the first surface n1 and a second intersection line of the second surface n2. Both the first intersection line and the second intersection line are straight lines. In some embodiments, referring to FIG. 6, the taper structure G2 is a triangular taper structure.

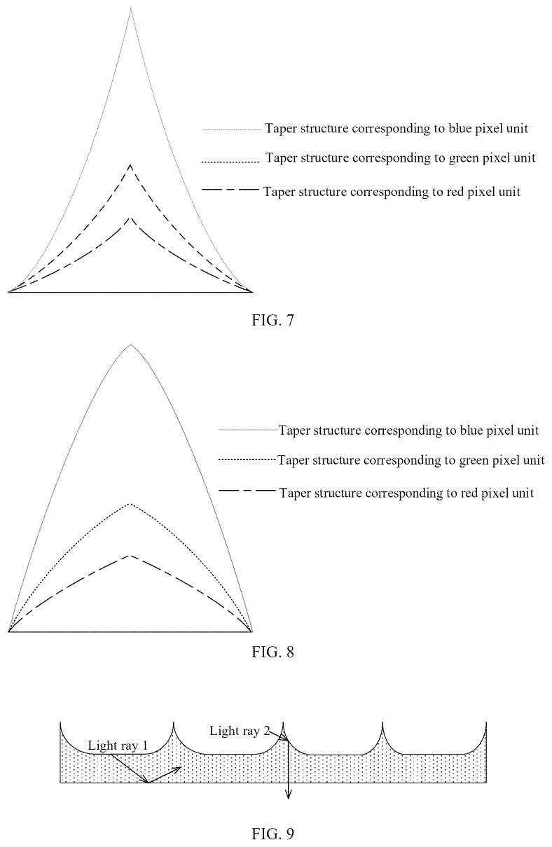

Alternatively, both the first intersection line and the second intersection line are curves. In some embodiments, referring to FIG. 7, the taper structure G2 is a sharp taper structure; or referring to FIG. 8, the taper structure G2 is an obtuse taper structure.

Both the first intersection line and the second intersection line are intersection lines of the middle portion G23 of the taper structure G2 with a reference plane. The reference plane is perpendicular to a length direction of the taper structure G2 and perpendicular to the bearing surface of the substrate 101. The first intersection line and the second intersection line are symmetrical relative a central axis of the taper structure G2.

In some embodiments of the present disclosure, the lens assembly G is disposed in other regions (e.g., at any position of the display region 101a of the display panel 10) in addition to the light-emitting region of the pixel unit 102. The disposing location of the lens assembly G is not limited in the embodiments of the present disclosure.

In some embodiments of the present disclosure, referring to FIG. 1, the display panel 10 further includes: a color filter layer 105 disposed between the organic insulating layer 103 and the driver circuit 1021. The color filter layer 105 includes color filter blocks 1051 of different colors, wherein an orthographic projection of each color filter block 1051 on the substrate 101 covers a light-emitting region of a pixel unit 102.

In some embodiments, the color filter layer 105 includes: a blue color filter block, a green color filter block, and a red color filter block. An orthographic projection of the blue color filter block on the substrate 101 covers the light-emitting region of the blue pixel unit, an orthographic projection of the green color filter block on the substrate 101 covers the light-emitting region of the green pixel unit, and an orthographic projection of the red color filter block on the substrate 101 covers the light-emitting region of the red pixel unit.

In some embodiments, the light-emitting side of the display panel 10 is the side, away from the pixel units 102, of the substrate 101. That is, the display panel 10 is bottom-emitting.

Referring to FIG. 9, the first surface n1 and the second surface n2 are configured to reflect light from the side of the substrate 101. Moreover, the light reflected by the first surface n1 and the second surface n2 passes through the color filter block 1051 and exits from the side, away from the pixel unit 102, of the substrate 101. As a result, the light confined to the interior of the display panel 10 is reflected by the first surface n1 or the second surface n2 and then exits through the color filter block 1051, which increases the light-emitting amount of the display panel 10 and improves the display effect.

FIG. 9 merely illustrates light paths of two light rays in the organic insulating layer 103. Light ray 1 is a light ray with a large angle on a flat surface, which is fully reflected at the interface of the substrate 101 and the air and cannot exit. Light ray 2 is a light ray with a large angle in a bevel surface, the light path of which is changed upon reflection at the bevel surface of the taper structure G2, and thus is able to exit, thereby improving the light extraction effect.

In some embodiments of the present disclosure, the driver circuit 1021 of each pixel unit 102 includes a plurality of thin film transistors and at least one storage capacitor. In some embodiments, the driver circuit 1021 includes seven thin film transistors and one storage capacitor, i.e., the driver circuit 1021 is a 7T1C driver circuit. Alternatively, the driver circuit 1021 includes other numbers of thin film transistors and other numbers of storage capacitors. The number of thin film transistors and the number of storage capacitors included in the driver circuit 1021 are not limited in the embodiments of the present disclosure.

Each thin film transistor includes a gate, a source, and a drain. The plurality of thin film transistors included in the driver circuit 1021 are connected to each other to drive the light-emitting unit 1022 to emit light. Only one thin film transistor in the driver circuit 1021 connected to the light-emitting unit 1022 is shown in FIG. 1.

Referring to FIG. 1, the driver circuit 1021 includes a gate layer m1, a gate insulating layer m2, an active layer m3, a source-drain layer m4, and an inorganic insulating layer m5 that are disposed on a side of the substrate 101 and sequentially stacked.

In some embodiments, the gate layer m1 includes a plurality of gate patterns, wherein each gate pattern serves as a gate of a thin film transistor. The active layer m3 includes a plurality of active patterns. The source-drain layer m4 includes a plurality of source patterns and a plurality of drain patterns, wherein any of the source patterns as well as any of the drain patterns are connected to a corresponding active pattern. Each source pattern and the corresponding drain pattern respectively serve as a source and a drain of a thin film transistor. The inorganic insulating layer m5 is a passivation layer (PVX).

In summary, the embodiments of the present disclosure provide a display panel. The display panel includes a substrate, and a plurality of pixel units and an organic insulating layer disposed on the substrate. The organic insulating layer is disposed between a driver circuit and a light-emitting unit of the pixel unit, and a lens assembly is arranged on a surface, away from the substrate, of a portion of the organic insulating layer within a light-emitting region of the pixel unit. The lens assembly includes a plurality of lenses with any two adjacent lenses forming a taper structure. A first surface and a second surface, away from the substrate, of the taper structure are configured to reflect the light confined to the interior of the display panel to the light-emitting side, which improves the light-emitting amount and the light extraction effect and ensures the light-emitting effect of the display panel.

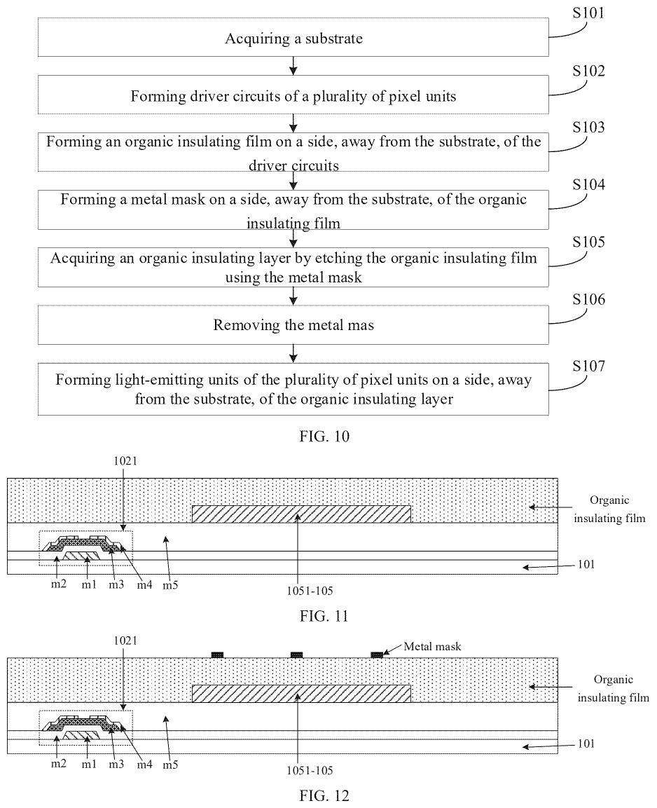

FIG. 10 is a flowchart of a method for manufacturing a display panel according to some embodiments of the present disclosure. Referring to FIG. 10, the method includes the following processes.

In process S101, a substrate is acquired.

In the embodiments of the present disclosure, when manufacturing the display panel 10, a substrate 101 is acquired first. In some embodiments, the substrate 101 is a glass substrate or a flexible substrate, which is not limited in the embodiments of the present disclosure.

In process S102, driver circuits of a plurality of pixel units are formed.

In some embodiments of the present disclosure, various film layers of the driver circuit 1021 are first sequentially formed on the substrate 101. In some embodiments, a gate layer, a gate insulating layer, an active layer, a source-drain layer, and an inorganic insulating layer are sequentially formed.

The gate layer, the active layer, and the source-drain layer are formed by a patterning process. The patterning process includes: photoresist coating, exposure, development, etching, and removal of the photoresist.

In process S103, an organic insulating film is formed on a side, away from the substrate, of the driver circuits.

In some embodiments of the present disclosure, referring to FIG. 11, an organic insulating film is formed on the side, away from the substrate 101, of the driver circuit 1021, and the surface, away from the substrate 101, of the organic insulating film is a flat surface. In some embodiments, the material of the organic insulating film is resin.

In process S104, a metal mask is formed on the side, away from the substrate, of the organic insulating film.

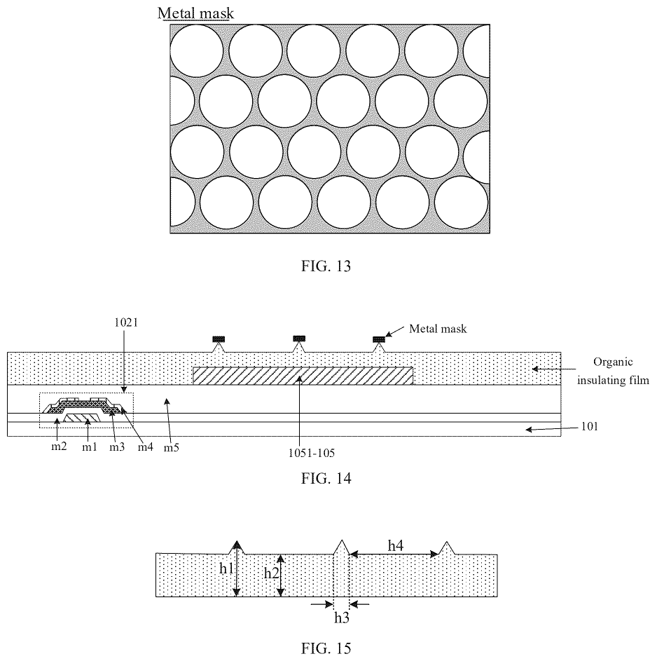

In some embodiments of the present disclosure, referring to FIG. 12, a metal film is formed on the side, away from the substrate 101, of the organic insulating film, and then a metal mask is acquired by processing the metal film using a patterning process. Referring to FIG. 13, the shape of the metal mask is approximately the same as the shape of the taper structure G2 to be formed subsequently. In some embodiments, the material of the metal mask is molybdenum (Mo), or other metal materials, which is not limited in the embodiments of the present disclosure.

In process S105, an organic insulating layer is acquired by etching the organic insulating film using the metal mask.

In the embodiments of the present disclosure, referring to FIG. 14, upon forming the metal mask, the organic insulating film is etched based on the metal mask to acquire the organic insulating layer 103. On the surface, away from the substrate 101, of the organic insulating film, the organic insulating material at the position not covered by the metal mask is partially etched, and the organic insulating material at the position covered by the metal mask is retained.

In some embodiments, the lens assembly G includes a plurality of lenses with any two adjacent lenses forming a taper structure G2, wherein each taper structure G2 includes a first surface n1 and a second surface n2 on a side, away from the substrate 101, of the taper structure G2. Both the first surface n1 and the second surface n2 are configured to increase the light-emitting amount and thus ensure the light-emitting effect of the display panel 10.

The taper structure G2 of the organic insulating layer 103 at a surface, away from the substrate 101, of the organic insulating layer 103 has approximately the same shape as the metal mask, but possibly has some differences in dimensions due to etching deviations of the process. In some embodiments, the width of the metal mask is greater than the width of the top (one end away from the substrate 101) of the taper structure G2, and smaller than or equal to the width of the bottom (one end close to the substrate 101) of the taper structure G2.

It is noted that for the sharp taper structure, the reactive ion etching (RIE) is employed; and for the obtuse taper structure, the photoresist used for etching is a positive photoresist.

FIG. 15 is a partial schematic diagram of another organic insulating layer according to some embodiments of the present disclosure. In FIG. 15, a distance h1 between the surface, close to the substrate 101, of the organic insulating layer 103 and the top of the taper structure G2 is 2.15 μm. A distance h2 between the surface, close to the substrate 101, of the organic insulating layer 103 and the surface, away from the substrate 101, of the organic insulating layer 103 without the taper structure G2 is 1.47 μm. A width h3 of the bottom of the taper structure G2 is 1.04 μm, and the distance h4 between two taper structures G2 that are parallel to each other is 3.19 μm.

In process S106, the metal mask is removed.

In the embodiments of the present disclosure, upon acquiring the lens assembly G by etching the organic insulating film, the metal mask is removed. That is, the metal mask does not exist in the display panel ultimately formed, and the metal mask is only used to form the taper structure G2.

In process S107, light-emitting units of the plurality of pixel units are formed on a side, away from the substrate, of the organic insulating layer.

In some embodiments of the present disclosure, upon forming the organic insulating layer 103, the light-emitting units 1022 of the plurality of pixel units 102 are subsequently formed on the side, away from the substrate 101, of the organic insulating layer 103. The light-emitting unit 1022 is connected to the driver circuit 1021 to receive a drive signal from the driver circuit 1021.

The process of forming the light-emitting unit 1022 includes: forming an anode layer 10221 on the side, away from the substrate 101, of the organic insulating layer 103, the anode layer 10221 including a plurality of anode patterns; forming a pixel defining layer 104 on the side, away from the substrate 101, of the anode layer 10221, the pixel defining layer 104 having a plurality of hollow regions, each of hollow regions exposing one anode pattern; forming a light-emitting layer 10222, the light-emitting layer 10222 including a plurality of light-emitting patterns, each of the light-emitting patterns being within one of the hollow regions and in contact with the anode pattern exposed by the hollow region; forming a cathode layer 10223 on the side, away from the substrate 101, of the light-emitting layer 10222, the cathode layer 10223 being shared by the plurality of light-emitting units 1022. In some embodiments, the material of the anode layer 10221 is indium tin oxide (ITO). In some embodiments, the light-emitting layer 10222 and the cathode layer 10223 are formed using a vapor deposition process.

Further, in some embodiments, upon forming the plurality of light-emitting units 1022, the plurality of light-emitting units 1022 are packaged. That is, a packaging layer is formed on a side, away from the substrate 101, of the plurality of light-emitting units 1022.

In some embodiments, the packaging layer includes: a first film layer, a second film layer, and a third film layer that are stacked in a direction away from the substrate 101.

In some embodiments, the first film layer and the third film layer are made of an inorganic material, and the second film layer is made of an organic material. In some embodiments, the first film layer and the third film layer are made of one or more inorganic oxides such as SiNx, SiOx, and SiOxNy. In some embodiments, the second film layer is made of resin. In some embodiments, the resin is thermoplastic resin or thermosetting resin, wherein the thermoplastic resin includes acrylic (PMMA) resin, and the thermosetting resin includes epoxy resin.

In some embodiments of the present disclosure, the second film layer is made by an inkjet printing (IJP) method. In some embodiments, the first film layer and the third film layer are formed by a chemical vapor deposition (CVD) method.

In summary, the embodiments of the present disclosure provide a method for manufacturing a display panel, the display panel manufactured by the method includes a substrate, and a plurality of pixel units and an organic insulating layer disposed on the substrate. The organic insulating layer is disposed between a driver circuit and a light-emitting unit of the pixel unit, and a lens assembly is arranged on a surface, away from the substrate, of a portion of the organic insulating layer within a light-emitting region of the pixel unit. The lens assembly includes a plurality of lenses with any two adjacent lenses forming a taper structure. A first surface and a second surface, away from the substrate, of the taper structure are configured to reflect the light confined to the interior of the display panel to the light-emitting side, which improves the light-emitting amount and the light extraction effect and ensures the light-emitting effect of the display panel.

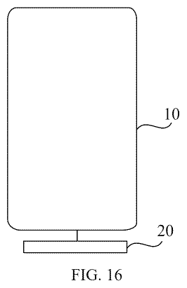

FIG. 16 is a schematic structural diagram of a display device according to some embodiments of the present disclosure. Referring to FIG. 16, the display device includes a power supply assembly 20 and a display panel 10 as provided in the above embodiments. The power supply assembly 20 is configured to supply power to the display panel 10.

In some embodiments, the display device is an organic light-emitting diode (OLED) display device. The display device is any suitable display device including, but not limited to, mobile phones, tablet computers, televisions, monitors, laptops, digital photo frames, navigators, e-books, and any other products or components with display functions.

Because the display device achieves essentially the same technical effect as the display panel described in the previous embodiments, the technical effect of the display device is not repeated herein for the purpose of brevity.

It should be understood that the terms used in the embodiments of the present disclosure are used for the purpose of explaining the embodiments of the present disclosure and are not intended to limit the present disclosure. Unless otherwise defined, technical or scientific terms used in the embodiments of the present disclosure should have the ordinary meaning understood by a person of ordinary skill in the art to which the present disclosure belongs.

In the description and the claims of the present disclosure, the terms “first,” “second,” “third,” or the like are used for distinguishing different components only and are not to be construed as indicating or implying any sequence, number, or relative importance. Similarly, similar terms such as “one” or “a” do not indicate a quantitative limitation, but indicate the existence of at least one object. Similar terms such as “include” or “comprise” mean that the element or object appearing before “include” or “comprise” covers the element, object, or their equivalents appearing behind “include” or “comprise”, but do not exclude other elements or objects. The terms such as “connect to” or “connected with” are not limited to physical or mechanical connections, but include electrical connections, no matter direct or indirect. The terms “up,” “down,” “left,” or “right” are used only to indicate relative positional relationships, and in the case that the absolute position of the described object is changed, the relative positional relationship is also possible to change accordingly.

The foregoing are only optional embodiments of the present disclosure, and are not intended to limit the present disclosure, and any modifications, equivalent substitutions, improvements, etc. made within the concept and principles of the present disclosure shall be included in the scope of protection of the present disclosure.

1. A display panel, comprising:
a substrate, wherein the substrate comprises a display region and a peripheral region surrounding the display region;
a plurality of pixel units, wherein the plurality of pixel units are disposed on a side of the substrate and within the display region, and each of the plurality of pixel units comprises a driver circuit and a light-emitting unit, the light-emitting unit being connected to the driver circuit to receive a drive signal from the driver circuit; and
an organic insulating layer, wherein the organic insulating layer is disposed between the driver circuit and the light-emitting unit;
wherein a lens assembly is arranged on a surface, away from the substrate, of a portion of the organic insulating layer within a light-emitting region of the pixel unit, the lens assembly comprising a plurality of lenses with adjacent lenses forming taper structures, at least one of the taper structures comprising a first surface and a second surface on a side, away from the substrate, of the at least one of taper structures.

2. The display panel according to claim 1, wherein each of the taper structures comprises a first end, a second end, and a middle portion between the first end and the second end, at least one of the first end or the second end of each of the taper structures being connected to a first end or a second end of another taper structure;
wherein a width of an orthographic projection of each of the first end and the second end of the taper structure on the substrate is greater than a width of an orthographic projection of the middle portion of the taper structure on the substrate, a direction of the width being perpendicular to a direction of a line connecting the first end and the second end.

3. The display panel according to claim 1, wherein each of the taper structures comprises a first end, a second end, and a middle portion between the first end and the second end, at least one of the first end or the second end of each of the taper structures being connected to a first end or a second end of another taper structure;
wherein a height of each of the first end and the second end of the taper structure is greater than a height of the middle portion of the taper structure, a direction of the height being perpendicular to a bearing surface of the substrate.

4. The display panel according to claim 1, wherein a mesh structure is formed on a side, away from the substrate, of the taper structure, the mesh structure comprising a plurality of grids arranged in an array, wherein the plurality of grids have the same shape.

5. The display panel according to claim 4, wherein at least one of the grids in the mesh structure is shaped as a quadrilateral or a hexagon.

6. The display panel according to claim 4, wherein an orthographic projection of a region enclosed by at least one of the grids on the substrate is shaped as a circle.

7. The display panel according to claim 1, wherein an area of a surface, away from the substrate, of the taper structure within a light-emitting region of any of the plurality of pixel units is smaller than an area of the light-emitting region of the pixel unit.

8. The display panel according to claim 1, wherein the light-emitting unit comprises an anode layer, a light-emitting layer, and a cathode layer that are sequentially stacked in a direction away from the substrate, and the display panel further comprises a pixel defining layer; wherein
the anode layer comprises a plurality of anode patterns;
the pixel defining layer comprises a plurality of hollow regions, each of the hollow regions exposing one of the anode patterns;
the light-emitting layer comprises a plurality of light-emitting patterns, each of the light-emitting patterns being in contact with one of the anode patterns through one of the hollow regions; and
the cathode layer is in contact with the light-emitting pattern; wherein
the hollow region is the light-emitting region; and
a total thickness of the anode pattern, the light-emitting pattern, and a portion of the cathode layer on the first surface and the second surface is less than a total thickness of the anode pattern, the light-emitting pattern, and other portion of the cathode layer.

9. The display panel according to claim 1, wherein
the plurality of pixel units comprise a first pixel unit, a second pixel unit, and a third pixel unit; and
the lens assembly comprises a first-type lens assembly, a second-type lens assembly, and a third-type lens assembly, an orthographic projection of the first-type lens assembly on the substrate being within a light-emitting region of the first pixel unit, an orthographic projection of the second-type lens assembly on the substrate being within a light-emitting region of the second pixel unit, an orthographic projection of the third-type lens assembly on the substrate being within a light-emitting region of the third pixel unit;
wherein a first angle defined between a first surface or a second surface of a taper structure formed by a lens of the first-type lens assembly and a bearing surface of the substrate, a second angle defined between a first surface or a second surface of a taper structure formed by a lens of the second-type lens assembly and the bearing surface of the substrate, and a third angle defined between a first surface or a second surface of a taper structure formed by a lens of the third-type lens assembly and the bearing surface of the substrate are different from each other.

10. The display panel according to claim 9, wherein
the first pixel unit is a blue pixel unit, the second pixel unit is a green pixel unit, and the third pixel unit is a red pixel unit; and
the first angle is greater than the second angle, and the second angle is greater than the third angle.

11. The display panel according to claim 10, wherein the first angle ranges from 56 degrees to 60 degrees, the second angle ranges from 40 degrees to 44 degrees, and the third angle ranges from 29 degrees to 33 degrees.

12. The display panel according to claim 1, wherein any of the taper structures comprises a first intersection line of the first surface and a second intersection line of the second surface;
wherein both the first intersection line and the second intersection line are straight lines; or, both the first intersection line and the second intersection line are curves; wherein
both the first intersection line and the second intersection line are intersection lines of a middle portion of the taper structure with a reference plane, the reference plane being perpendicular to a length direction of the taper structure and perpendicular to a bearing surface of the substrate; and
the first intersection line and the second intersection line are symmetrical relative to a central axis of the taper structure along the length direction.

13. The display panel according to claim 1, further comprising: a color filter layer disposed between the organic insulating layer and the driver circuit, the color filter layer comprising a plurality of color filter blocks of different colors; wherein
an orthographic projection of each of the color filter blocks on the substrate covers a light-emitting region of one of the plurality of pixel units.

14. The display panel according to claim 13, wherein
a light-emitting side of the display panel is a side, away from the plurality of pixel units, of the substrate; and
the first surface and the second surface are configured to reflect light from a side of the substrate, and the reflected light by the first surface and the second surface passes through any of the plurality of color filter blocks and exits from the side, away from the plurality of pixel units, of the substrate.

15. A method for manufacturing a display panel, comprising:
acquiring a substrate, wherein the substrate comprises a display region and a peripheral region surrounding the display region;
forming driver circuits of a plurality of pixel units;
forming an organic insulating film on a side, away from the substrate, of the driver circuits;
forming a metal mask on a side, away from the substrate, of the organic insulating film;
acquiring an organic insulating layer by etching the organic insulating film using the metal mask;
removing the metal mask; and
forming light-emitting units of the plurality of pixel units on a side, away from the substrate, of the organic insulating layer, the light-emitting units being connected to the driver circuits to receive drive signals from the driver circuits;
wherein a lens assembly is arranged on a surface, away from the substrate, of a portion of the organic insulating layer within a light-emitting region of any of the plurality of pixel units, the lens assembly comprising a plurality of lenses with adjacent lenses forming taper structures, at least one of the taper structures comprising a first surface and a second surface on a side, away from the substrate, of the at least one of taper structures.

16. A display device, comprising: a power supply assembly, and a display panel,
the power supply assembly being configured to supply power to the display panel;
wherein the display panel comprises:
a substrate, wherein the substrate comprises a display region and a peripheral region surrounding the display region;
a plurality of pixel units, wherein the plurality of pixel units are disposed on a side of the substrate and within the display region, and each of the plurality of pixel units comprises a driver circuit and a light-emitting unit, the light-emitting unit being connected to the driver circuit to receive a drive signal from the driver circuit; and
an organic insulating layer, wherein the organic insulating layer is disposed between the driver circuit and the light-emitting unit;
wherein a lens assembly is arranged on a surface, away from the substrate, of a portion of the organic insulating layer within a light-emitting region of the pixel unit, the lens assembly comprising a plurality of lenses with adjacent lenses forming taper structures, at least one of the taper structures comprising a first surface and a second surface on a side, away from the substrate, of the at least one of taper structures.

17. The display device according to claim 16, wherein each of the taper structures comprises a first end, a second end, and a middle portion between the first end and the second end, at least one of the first end or the second end of each of the taper structures being connected to a first end or a second end of another taper structure;
wherein a width of an orthographic projection of each of the first end and the second end of the taper structure on the substrate is greater than a width of an orthographic projection of the middle portion of the taper structure on the substrate, a direction of the width being perpendicular to a direction of a line connecting the first end and the second end.

18. The display device according to claim 16, wherein each of the taper structures comprises a first end, a second end, and a middle portion between the first end and the second end, at least one of the first end or the second end of each of the taper structures being connected to a first end or a second end of another taper structure;
wherein a height of each of the first end and the second end of the taper structure is greater than a height of the middle portion of the taper structure, a direction of the height being perpendicular to a bearing surface of the substrate.

19. The display device according to claim 16, wherein a mesh structure is formed on a side, away from the substrate, of the taper structure, the mesh structure comprising a plurality of grids arranged in an array, wherein the plurality of grids have the same shape.

20. The display device according to claim 19, wherein at least one of the grids in the mesh structure is shaped as a quadrilateral or a hexagon.
